(19) United States
(12) Patent Application Publication
(10) Pub. No.: US 2026/0174199 A1
(43) Pub. Date: Jun. 25, 2026

(54) EXTERNAL PART COMPRISING A STACK OF INTERFERENCE LAYERS DEPOSITED ON A FACE COMPRISING AT LEAST 50% BY MASS OF TITANIUM

(71) Applicant: The Swatch Group Research and Development Ltd., Marin (CH)

(72) Inventors: Camille HALLER, Yverdon-les-Bains (CH); Loic CURCHOD, Lausanne (CH); Marie BAUDOZ, Morteau (FR); Giovanni POLY, Maiche (FR)

(73) Assignee: The Swatch Group Research and Development Ltd., Marin (CH)

(21) Appl. No.: 19/390,993

(22) Filed: Nov. 17, 2025

(30) Foreign Application Priority Data
Dec. 20, 2024 (EP) 24222572.0

(51) Int. Cl. A44C 15/00; C23C 16/40; C23C 16/455

(52) U.S. Cl. CPC A44C 15/00; C23C 16/403; C23C 16/405; C23C 16/45529; C23C 16/45555

(57) ABSTRACT

An external part (10) used in horology, jewellery or fine jewellery, including a substrate (100) having a support face (101) made of a material including at least 50% by mass of titanium, on which is deposited a semi-transparent thin-film dielectric coating including at least three layers, including a base layer (111) made of TiO₂ overlying the support face (101), a terminal layer (112) made of TiO₂ and an intermediate layer (113) made of Al₂O₃ and deposited between the base layer (111) and the terminal layer (112).

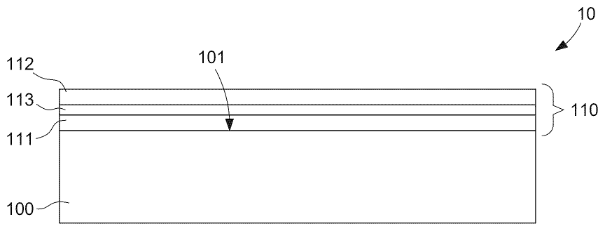

### CROSS-REFERENCE TO RELATED APPLICATIONS

This application claims priority to European Patent Application No. 24222572.0, filed on Dec. 20, 2024, the entire contents of which are incorporated herein by reference.

### TECHNICAL FIELD OF THE INVENTION

The invention relates to the field of horology, jewellery or fine jewellery, and more specifically to an external part for use in horology, jewellery or fine jewellery.

In this specification, the term “external part” refers, as is commonly understood in the aforementioned fields, to a component that is visible to a user and has a decorative function, meaning that it contributes to the visual appearance of an object.

### TECHNOLOGICAL BACKGROUND

In the fields of horology, jewellery and fine jewellery, market players are constantly on the lookout for new decorative solutions to change the appearance of their products in order to enhance product appeal or to stand out from the competition.

For example, and particularly in the field of horology, it is common to colour external parts by depositing thin layers on a substrate using vacuum deposition methods, such as physical vapour phase deposition or chemical vapour phase deposition. However, depending on the nature of the substrate and of the layers deposited, adhesion problems may arise. This drawback requires the deposition of an adhesion layer, which further complicates the component colouring method.

With regard to external parts comprising a substrate made of titanium, the aforementioned drawback can be remedied by using a method for anodising the substrate in order to colour the external part. However, anodising is a relatively long process insofar as it requires long cycle times to grow an oxide layer on the substrate and involves a multitude of steps. Moreover, between each step, the external parts have to be handled, which increases the risk of damaging them.

### SUMMARY OF THE INVENTION

The invention remedies the aforementioned disadvantages, and relates, to this end, to an external part used in horology, jewellery or fine jewellery, comprising a substrate having a support face made of a material comprising at least 50% by mass of titanium, on which is deposited a semi-transparent thin-film dielectric coating comprising at least three layers, including a base layer made of TiO₂ overlying the support face, a terminal layer made of TiO₂ and an intermediate layer made of Al₂O₃ and deposited between the base layer and the terminal layer.

The invention advantageously ensures excellent adhesion between the support face and the thin-film dielectric coating due to the chemical affinity between said face and the base layer. Layering can also be used to impart a bright and precise colour to the external part.

In particular embodiments, the invention can further comprise one or more of the following features, taken separately or in any technically possible combination.

In some particular embodiments, the substrate is formed by a body made of pure titanium or of a titanium alloy and comprising the support face.

In some particular embodiments, the substrate comprises a body on which is formed a plating made of titanium nitride, titanium carbide, titanium oxide or titanium carbonitride, the plating comprising the support face.

In some particular embodiments, the thin-film dielectric coating comprises three intermediate layers in which two thin films made of Al₂O₃ are separated by a layer made of TiO₂.

In some particular embodiments, the layers in the thin-film dielectric coating have thicknesses chosen so as to impart an interference colour to the external part characterised, in the CIELAB space in the reflection mode of the standardised illuminant D65, with an observer of 10° and a measurement geometry of di:8°, by the parameters L=[20; 30], a*=[0; 10], b*=[−5; 5].

In some particular embodiments, the base layer has a thickness comprised between 20 nm and 30 nm, the intermediate layer has a thickness comprised between 1 nm and 10 nm, and the terminal layer has a thickness comprised between 1 nm and 5 nm.

### BRIEF DESCRIPTION OF THE FIGURES

Other characteristics and advantages of the invention will become apparent from the following detailed description, which is given by way of non-limiting example, with reference to the FIGURE, which shows a schematic cross-sectional view of an external part respectively according to a preferred exemplary embodiment of the present invention.

It should be noted that the FIGURE is not drawn to scale for clarity reasons.

### DETAILED DESCRIPTION OF THE INVENTION

The present invention relates to an external part 10 used in horology, jewellery or fine jewellery, comprising a substrate 100 having a support face 101 made of a material comprising at least 50% by mass of titanium, that is, made of a material comprising titanium.

The external part 10 according to the invention is schematically shown in the FIGURE and is particularly suitable for forming a dial for a timepiece, or any other part of the timepiece, preferably an internal part, such as appliques or hands.

In the present text, the substrate can be made of pure titanium, a titanium alloy, a titanium nitride, a titanium carbide, a titanium oxide, a titanium carbonitride, etc.

The substrate 100 is formed by a body which, in an exemplary embodiment of the invention, is made of a material comprising at least 50% by mass of titanium. The support face 101 is therefore formed by one face of the body.

In other exemplary embodiments of the invention, the substrate 100 can comprise a body made, for example, from a material other than titanium and on which a plating comprising at least 50% by mass of titanium is formed. The support face 101 is therefore formed by a face of the plating.

Naturally, the type of material comprising at least 50% by mass of titanium determines whether the support face 101 is formed by the body or by the plating. For example, if the material comprising at least 50% by mass of titanium is pure titanium or a titanium alloy, it can form the body of the substrate 100. If the material comprising at least 50% by mass of titanium is titanium nitride, titanium carbide or titanium carbonitride, it can constitute a plating deposited by suitable deposition methods, such as physical vapour phase deposition methods or chemical vapour phase deposition methods. Moreover, if the material comprising at least 50% by mass of titanium is a titanium oxide, it can constitute a plating produced by anodisation, in a manner known per se to a person skilled in the art.

The external part 10 comprises, on its support face 101, a thin-film dielectric coating 110 that is semi-transparent, that is, at least transparent in the visible range. The thin-film dielectric coating comprises at least three layers, each of which is deposited by an atomic thin-film deposition method known to the person skilled in the art by the acronym “ALD” in English for “Atomic Layer Deposition”. Each layer in the thin-film dielectric coating 110 has a thickness comprised between one nanometre and a few tens of nanometres. This characteristic makes it possible to protect the support face 101 of the external part 10 from chemical and environmental aggressions, such as humidity, and to colour it by a precisely chosen interference effect in a repeatable and robust way. The thickness of the thin-film dielectric coating 110 is therefore homogeneous and consistent across its entire surface.

The support face 101 can have structuring, for example by mechanical machining, for example by manual engraving or machining with a numerically controlled machine tool, by chemical machining or by laser machining. The structuring is formed by hollows and peaks, the distance between the hollows and peaks being, for example, at least 1 μm, and its appearance is advantageously preserved by the thin-film dielectric coating 110.

The thin-film dielectric coating 110 is formed by at least three thin dielectric films, including a base layer 111 overlying the support face 101, a terminal layer 112 and an intermediate layer 113 deposited between the base layer 111 and the terminal layer 112, as can be seen in the FIGURE.

The base layer 111 and the terminal layer 112 are made of TiO₂ and the intermediate layer 113 is made of Al₂O₃. In particular, the terminal layer 112 made of TiO₂ advantageously ensures the chemical protection of the external part.

It should be noted that the thin-film dielectric coating 110 can comprise three intermediate layers 113, in which two thin films made of Al₂O₃ are separated by a layer made of TiO₂.

Moreover, it can be foreseen that the thin-film dielectric coating 110 comprises more than three intermediate layers 113, provided that these layers consist of alternating layers made of Al₂O₃ and TiO₂, and that the intermediate layers 113 arranged against the base layer 111 and against the terminal layer 112 are made of Al₂O₃.

Advantageously, the base layer 111 has excellent chemical affinity with the support face 101 on which it is deposited, which ensures very good adhesion of the base layer 111 and therefore of the thin-film dielectric coating 110, and makes it possible to increase the deposition rate of the base layer 111.

The thin-film dielectric coating 110 imparts an interference colour to the external part 10, the hue of which depends on the thickness of each thin film in the thin-film dielectric coating 110, on their arrangement and number, and on the material of the support face 101. Thus, the interference colour generated by the characteristics of the invention is advantageously very precise.

In one preferred exemplary embodiment of the invention, the layers in the thin-film dielectric coating 110 have thicknesses chosen so as to impart an interference colour to the external part 10 characterised, in the CIELAB space in the reflection mode of the standardised illuminant D65, with an observer of 10° and a measurement geometry of di:8°, by the parameters L*=[20; 30], a*=[0; 10], b*=[−5; 5], and more specifically by the parameters L*=26, a* =30, b*=4.

Thus, in this first variant, the external part 10 has a burgundy red appearance.

In this preferred exemplary embodiment, each layer in the thin-film dielectric coating 110 has a thickness comprised between one and a few tens of nanometres, for example between 1 nm and 30 nm. In particular, the base layer 111 has a thickness comprised between 20 nm and 30 nm, the intermediate layer 113 has a thickness comprised between 1 nm and 10 nm, and the terminal layer 112 has a thickness comprised between 1 nm and 5 nm.

More generally, it should be noted that the embodiments and uses considered above have been described by way of non-limiting examples, and that other variants are therefore conceivable.

1. An external part used in horology, jewellery or fine jewellery, characterised in that it comprises a substrate having a support face made of a material comprising at least 50% by mass of titanium, on which is deposited a semi-transparent thin-film dielectric coating comprising at least three layers, including a base layer made of TiO₂ overlying the support face, a terminal layer made of TiO₂ and an intermediate layer made of Al₂O₃ and deposited between the base layer and the terminal layer.

2. The external part according to claim 1, in which the substrate is formed by a body made of pure titanium or of titanium alloy and comprising the support face.

3. The external part according to claim 1, in which the substrate comprises a body on which is formed a plating made of titanium nitride, titanium carbide, titanium oxide or titanium carbonitride, the plating comprising the support face.

4. The external part according to claim 1, in which thin-film dielectric coating comprises three intermediate layers, two of which are thin films made of Al₂O₃, separated by a layer made of TiO₂.

5. The external part according to claim 1 in which the layers in the thin-film dielectric coating have thicknesses chosen so as to impart an interference colour to the external part characterised, in the CIELAB space in the reflection mode of the standardised illuminant D65, with an observer of 10° and a measurement geometry of di:8°, by the parameters L*=[20; 30], a*=[0; 10], b*=[−5; 5].

6. The external part according to claim 5, in which the base layer has a thickness comprised between 20 nm and 30 nm, the intermediate layer has a thickness comprised between 1 nm and 10 nm and the terminal layer has a thickness comprised between 1 nm and 5 nm.
